(19) United States
(12) Patent Application Publication
(10) Pub. No.: US 2026/0107766 A1
(43) Pub. Date: Apr. 16, 2026

(54) SEMICONDUCTOR CHIP AND MANUFACTURING METHOD FOR THE SAME

(71) Applicant: Samsung Electronics Co., Ltd., Suwon-si (KR)

(72) Inventors: HYUNSOO CHUNG, Suwon-si (KR); KEUM-HEE MA, Suwon-si (KR)

(21) Appl. No.: 19/197,107

(22) Filed: May 2, 2025

(30) Foreign Application Priority Data
Oct. 14, 2024 (KR) 10-2024-0139842

(51) Int. Cl. H01L 23/367; H01L 21/308; H01L 21/3105; H01L 21/74; H01L 23/48; H01L 23/50

(52) U.S. Cl. CPC H10W 40/22; H10P 50/691; H10P 95/062; H10W 20/021; H10W 20/20; H10W 72/00

(57) ABSTRACT

A semiconductor chip includes a semiconductor substrate that includes a front side and a back side that are opposite to each other, a circuit structure disposed on the front side of the semiconductor substrate, a first through via that penetrates the semiconductor substrate in a vertical direction perpendicular to the front side of the semiconductor substrate and is electrically connected to the circuit structure, and a dummy via buried in the semiconductor substrate, wherein a lower end of the dummy via is spaced apart from the back side of the semiconductor substrate.

### CROSS-REFERENCE TO RELATED APPLICATION

This application claims priority to and the benefit of Korean Patent Application No. 10-2024-0139842 filed at the Korean Intellectual Property Office on Oct. 14, 2024, the entire contents of which are herein incorporated by reference.

### BACKGROUND OF THE INVENTION

### (a) Field of the Invention

The present disclosure relates to a semiconductor chip and a manufacturing method thereof.

### (b) Description of the Related Art

As the electron industry develops rapidly, users' demands are becoming more diverse. Users prefer smaller and lighter devices, and such a trend is affecting a variety of electronic products, including smartphones, tablets, and wearable devices. Accordingly, a semiconductor package, which is a core component of an electronic device, is also desirable to be miniaturized and light-weighted.

A miniaturized semiconductor package needs to simultaneously provide high performance and large capacity. In order to satisfy such a technological demand, various technologies are being researched in the semiconductor industry, and among them, through silicon via (TSV) technology, which vertically connects semiconductor chips, is attracting attention.

### SUMMARY OF THE INVENTION

One aspect of the present disclosure is intended to provide a semiconductor chip having excellent heat dissipation characteristics, and a manufacturing method thereof.

According to an aspect of the present disclosure, a semiconductor chip includes a semiconductor substrate that includes a front side and a back side that are opposite to each other, a circuit structure disposed on the front side of the semiconductor substrate, a first through via that penetrates the semiconductor substrate in a vertical direction perpendicular to the front side of the semiconductor substrate and is electrically connected to the circuit structure, and a dummy via buried in the semiconductor substrate, wherein a lower end of the dummy via is spaced apart from the back side of the semiconductor substrate.

According to an aspect of the present disclosure, a semiconductor chip includes a semiconductor substrate that includes a front side and a back side that are opposite to each other, a circuit structure disposed on the front side of the semiconductor substrate, a first pad that is disposed on the circuit structure and electrically connected to the circuit structure, a back side insulation layer that is disposed on the back side of the semiconductor substrate, a first through via that penetrates the semiconductor substrate and the back side insulation layer in a vertical direction perpendicular to the front side of the semiconductor substrate, and is electrically connected to the circuit structure, a via insulation layer that surrounds a side surface of the first through via, a dummy via buried in the semiconductor substrate, wherein the dummy via extends from the back side insulation layer toward the front side of the semiconductor substrate, a second pad that is disposed on the back side insulation layer and connected to the first through via, and a dummy pad that is disposed on the back side insulation layer and connected to the dummy via. The back side insulation layer extends into a space between the dummy via and the semiconductor substrate.

According to an aspect of the present disclosure, a semiconductor chip manufacturing method include forming a first through via covered with a via insulation layer in a semiconductor substrate having a front side and a preliminary back side which are opposite surfaces, wherein the first through via extends from the front side toward the preliminary back side in a vertical direction perpendicular to the front side of the semiconductor substrate, partially removing the semiconductor substrate from the preliminary back side thereof to form a back side, thereby the first through via and the via insulation layer protruding beyond the back side of the semiconductor substrate, forming a dummy via hole extending from the back side of the semiconductor substrate toward the front side thereof, forming a back side insulation layer covering the back side of the semiconductor substrate, a region of the via insulation layer protruding beyond the back side of the semiconductor substrate, and a wall side and a bottom side of the dummy via hole, forming a dummy via filling the dummy via hole, removing a portion of each of the back side insulation layer and the via insulation layer to expose the first through via, and forming a first pad connected to the first through via and a dummy pad connected to the dummy via.

According to one aspect of the present disclosure, a semiconductor chip having excellent heat dissipation characteristics, and a manufacturing method thereof can be provided.

### BRIEF DESCRIPTION OF THE DRAWINGS

FIG. 1 is a cross-sectional view of a semiconductor chip according to an embodiment.

FIG. 2 is an enlarged view of the region A of FIG. 1.

FIG. 3 is a cross-sectional view of a semiconductor chip according to another embodiment.

FIG. 4 is a cross-sectional view of a semiconductor chip according to another embodiment.

FIG. 5 to FIG. 11 show a manufacturing process of a semiconductor chip according to an embodiment.

### DETAILED DESCRIPTION OF THE EMBODIMENTS

Hereinafter, with reference to the accompanying drawings, various embodiments of the present disclosure are described in detail and thus a person of ordinary skill in the art to which the present disclosure belongs can easily practice the present disclosure. The present disclosure may be implemented in many different forms and is not limited to the embodiments described herein.

In order to clearly describe the present disclosure, parts that are not related to the description have been omitted, and the same reference symbols are used for identical or similar components throughout the specification.

The size and thickness of each component shown in the drawing are arbitrarily shown for better understanding and ease of description, and thus the present disclosure is not necessarily limited to what is shown. In the drawings, the thickness of layers, films, panels, regions, etc., are exaggerated for clarity. In the drawing, for better understanding and ease of description, the thickness of some layers and regions is exaggerated.

In the entire specification, when a part is “connected (connected, contacted, combined)” with another part, it is not only “directly connected”, but also “indirectly connected” with another member in the middle. From a similar perspective, this includes not only being “physically connected” but also being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above”or “on”in a direction opposite to gravity.

Unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross section obtained by cutting a target part vertically is viewed from the side.

Throughout the specification, the sequential numbers, such as first, second, and the like are used to distinguish a component from other identical or similar components, and are not necessarily intended to refer to a specific component. Thus, a component referred to as a first component in a particular part of this specification may be referred to as a second component in another part of this specification.

Throughout the specification, a singular reference to any component includes a plurality of references to that component, unless otherwise stated. For example, “insulation layer” may be used to mean not only one insulation layer, but also a plurality of insulation layers, such as two, three or more.

Further, throughout the specification, references to directions such as top, upper, upper side, lower, lower, and the like are provided with reference to the drawings to aid description and understanding.

Hereinafter, a semiconductor chip according to embodiments of the present disclosure will be described.

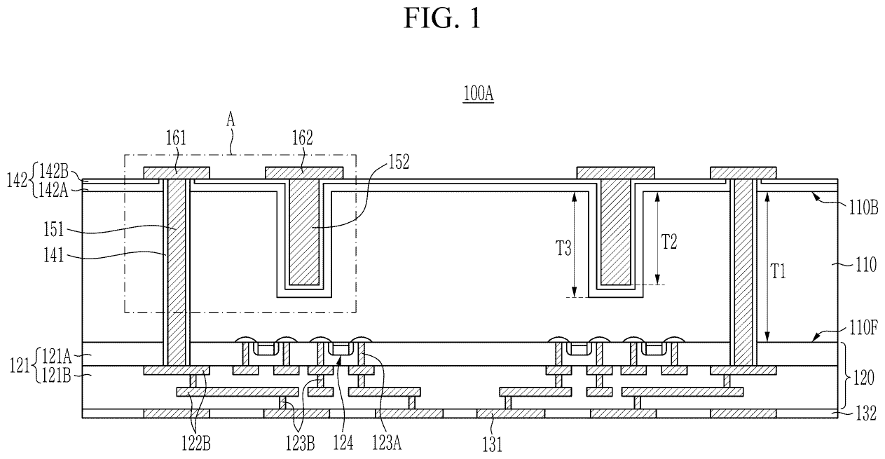

FIG. 1 is a cross-sectional view of a semiconductor chip according to an embodiment.

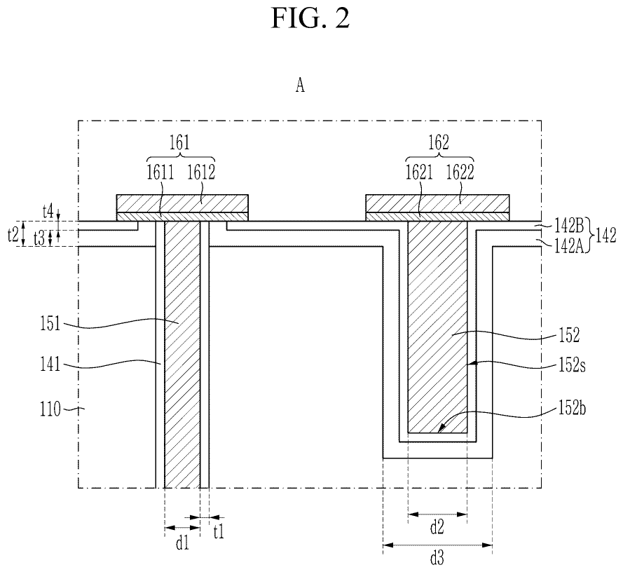

FIG. 2 is an enlarged view of the region A of FIG. 1.

A semiconductor chip 100A may include a semiconductor substrate 110, circuit structure 120, a first pad 131, a first through via 151, a second through via 152, a via insulation layer 141, a rear insulation layer 142, a second pad 161, a third pad 162. As used herein, the singular forms “a”, “an” and “the” are intended to include the plural forms as well, unless the context clearly indicates otherwise.

The semiconductor substrate 110 may have a front side 110F and the back side 110B, which are opposite to each other. The semiconductor substrate 110 may include a semiconductor element such as silicon (Si) or a compound semiconductor such as gallium arsenide (GaAs), and indium arsenide (InAs).

The circuit structure 120 may be disposed on the front side 110F of the semiconductor substrate 110.

The circuit structure 120 may be formed by a front end of line (FEOL) process and a back end of line (BEOL) process that are sequentially performed, and may include an individual device 124, interlayer insulating layers 121, wiring layers 122B, and vias 123A and 123B. The individual device 124, the interlayer insulating layer 121A, and the via 123A may be formed in the FEOL process, and the interlayer insulating layer 121B, the wiring layer 122B, and the via 123B may be formed in the BEOL process.

The individual device 124 is formed on the front side 110F of the semiconductor substrate 110 and may include at least one of, for example, a metal-oxide-semiconductor field effect transistor (MOSFET), a bipolar junction transistor (BJT), a diode, a light emitting diode (LED), a capacitor, an inductor, and a resistor. The individual devices 124 may be connected with each other to form a logic circuit and/or a memory circuit. As used herein, the term “and/or” includes any and all combinations of one or more of the associated listed items and may be abbreviated as “/”.

The interlayer insulating layer 121 covers the individual device 124, the wiring layer 122B, and the vias 123A and 123B, and may provide electrical insulation between the individual device 124 and the wiring layers 122B. The interlayer insulating layer 121A may cover the individual device 124 and the via 123A, and the interlayer insulating layer 121B may cover the wiring layer 122B and the via 123B. The interlayer insulating layer 121 may be formed of an insulating material, and may include, for example, at least one of silicon oxide and silicon nitride.

The wiring layer 122B may be electrically connected to the individual device 124 and a first pad 131. The wiring layer 122B may be formed of a conductive material and may include a metal such as, for example, copper (Cu), aluminum (Al), nickel (Ni), gold (Au), silver (Ag), palladium (Pd), titanium (Ti), and an alloy thereof.

The vias 123A and 123B may provide electrical connections between the individual device 124 and the wiring layers 122B arranged at different levels. The via 123A may be a contact via connecting the individual device 124 to the topmost wiring layer. The via 123B may connect the wiring layers 122B with each other or connect the wiring layer 122B to the first pad 131.

A passivation film 132 may be disposed on a circuit structure 120 to protect the semiconductor chip 100A. The passivation film 132 may have an opening that exposes at least a portion of the first pad 131 and may extend onto the first pad 131 as desired. The passivation film 132 may be formed of an insulating material, and may include, for example, an inorganic material such as silicon oxide and silicon nitride and/or an organic material such as polyimide (PI), epoxy, and silicon carbide (SiC).

The first pad 131 is disposed on the circuit structure 120 and may be electrically connected to the circuit structure 120. The first pad 131 may electrically connect the semiconductor chip 100A to other components. The first pad 131 may be formed of a conductive material and may include a metal such as, for example, copper (Cu), aluminum (Al), nickel (Ni), gold (Au), silver (Ag), palladium (Pd), titanium (Ti), and an alloy thereof. As necessary, the first pad 131 may be formed of a plurality of conductivity layers (e.g., a plurality of metal layers).

The first through via 151 penetrates the semiconductor substrate 110 and may be electrically connected to the circuit structure 120.

In an embodiment, the first through via 151 may be formed using a via middle process performed between the FEOL process and the BEOL process. For example, the first through via 151 may be formed between the FEOL process and the BEOL process. Therefore, the first through via 151 may further penetrate a portion (e.g., FEOL process region) of the circuit structure 120 on the semiconductor substrate 110. The first through via 151 may be electrically connected to the first pad 131 via the wiring layer 122B.

The area surrounding the first through via 151 may be set as a keep out zone (KOZ) where the formation of individual devices 124 is restricted. Therefore, the first through via 151 may be separated from the individual device 124 by a predetermined distance. The KOZ may prevent physical and electrical interferences from the first through via 151 to the individual device 124, thereby ensuring the performance and reliability of the semiconductor chip. In an embodiment, when viewed in a plan view, the first through via 151 may be spaced apart from the individual device 124 without overlapping.

A diameter d1 of the first through via 151 may be about 3.5 μm.

The first through via 151 may be formed of a conductive material, for example, doped silicon or a metal such as copper (Cu), tungsten (W), silver (Ag), nickel (Ni), and an alloy thereof.

The second through via 152 is a dummy through via that is not electrically connected to the circuit structure 120, and may serve to improve the heat dissipation characteristics of the semiconductor chip. For example, the second through via 152 may be a dummy via. As used herein, the term “dummy” is used to refer to a component that has the same or similar structure and shape as other components but does not have a substantial function and exists only as a pattern in the device.

The second through via 152 may penetrate a portion of the semiconductor substrate 110 in a vertical direction from the back side 110B of the semiconductor substrate 110 toward the front side 110F of the semiconductor substrate 110. The vertical direction may be perpendicular to the front side 110F of the semiconductor substrate 110. In an embodiment, when viewed in a plan view, the second through via 152 may overlap the individual device 124.

In an embodiment, the second through via 152 may be formed as a via last process performed after the FEOL process and the BEOL process. For example, the second through via 152 may be formed after the FEOL process and the BEOL process. The second through via 152 may be formed, for example, by forming a via hole (i.e., a dummy via hole) penetrating a portion of the semiconductor substrate 110 by processing the back side 110B of the semiconductor substrate 110, forming an insulation layer 142 along the wall and bottom sides of the via hole, and then filling the via hole with a conductive material.

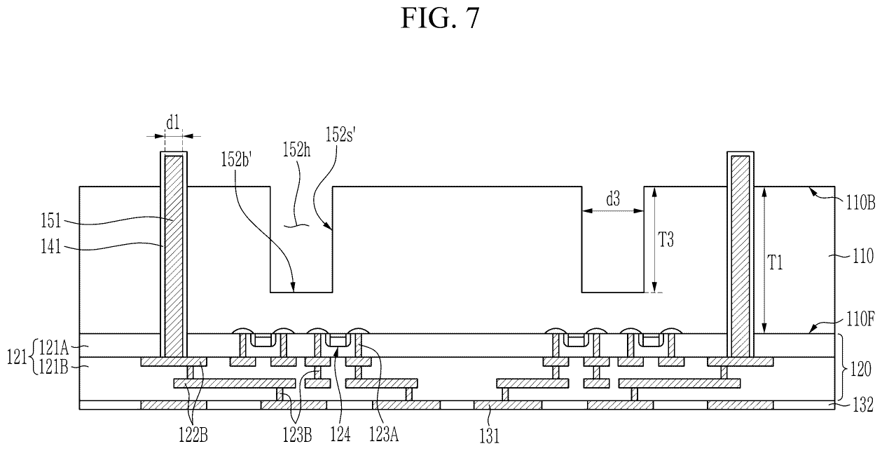

A depth T2 of the semiconductor substrate 110 through which the second through via 152 penetrates may be 50% or more of the thickness T1 of the semiconductor substrate 110. For example, a height T2, in the vertical direction, of the second through via 152 may be greater than 50% of the thickness T1, in the vertical direction, of the semiconductor substrate 100. By forming the depth T2 of the semiconductor substrate 110 through which the second through via 152 penetrates to be 50% or more of the thickness T1 of the semiconductor substrate 110, a semiconductor chip having excellent heat dissipation characteristics can be provided. As described later, a depth T3 of the via hole for forming the second through via 152 may be 50% or more of the thickness T1 of the semiconductor substrate 110 (refer to FIG. 7).

The second through via 152 may be separated from the individual device 124. By adjusting the depth T2 of the semiconductor substrate 110 through which the second through via 152 penetrates, the second through via 152 can be prevented from being in contact with the individual device 124. In an embodiment, a lower end of the second through via 152 may be spaced apart from the front side 110F of the semiconductor substrate 110 in the vertical direction.

At least a part of the second through via 152 may overlap the individual device 124. This is because, unlike first through via 151, the second through via 152 does not require to set the KOZ. By introducing the second through via 152 that does not require the KOZ, the heat dissipation characteristics can be improved without increasing the area of the semiconductor chip.

A diameter d2 of the second through via 152 may be greater than or equal to the diameter d1 of the first through via 151. For example, the diameter d2 of the second through via 152 may be approximately 3.5 μm to 10 μm. When the diameter d2 of the second through via 152 is too small, the heat dissipation effect may be minimal, and when it is too large, problems such as increased process time and cost, increased chip area, and increased mechanical stress may occur. As described later, a diameter d3 of the via hole for forming the second through via 152 may also be greater than the diameter d1 of the first through via 151 (refer to FIG. 7).

The second through via 152 may be formed of a conductive material, and may include, for example, doped silicon or a metal such as copper (Cu), tungsten (W), silver (Ag), nickel (Ni), and an alloy thereof.

The thermal conductivity of the second through via 152 may be higher than the thermal conductivity of the semiconductor substrate 110. For example, the semiconductor substrate 110 may be formed of silicon having a thermal conductivity of about 125 W/mK, and the second through via 152 may be formed of copper having a thermal conductivity of about 396 W/mK.

The via insulation layer 141 may surround a side surface of the first through via 151.

The via insulation layer 141 may be formed of an insulating material, such as, for example, silicon oxide.

The via insulation layer 141 may be formed by a deposition process such as chemical vapor deposition (CVD), physical vapor deposition (PVD), and atomic layer deposition (ALD).

The via insulation layer 141 may have a thin thickness. For example, a thickness t1 of the via insulation layer 141 may be about 0.3 μm. The thickness t1 of the via insulation layer 141 means a thickness in a horizontal direction from the first through via 151, which is a configuration covered by the via insulation layer 141, toward the via insulation layer 141. The horizontal direction may be parallel to the front side 110F of the semiconductor substrate 110. Since the first through via 151 has a relatively high aspect ratio (AR), the via insulation layer 141 with a thin thickness may be formed during the deposition process. The AR of the first through via 151 may refer to a ratio of its depth to its width.

A back side insulation layer 142 may be disposed on the back side 110B of the semiconductor substrate 110. The back side insulation layer 142 may contact and directly cover the back side 110B of the semiconductor substrate 110.

In an embodiment, the back side insulation layer 142 extends between the second through via 152 and the semiconductor substrate 110 and may also serve as a via insulation layer of the second through via 152. The back side insulation layer 142, which serve as a via insulation layer, may cover a side surface 152s and a bottom surface 152b of the second through via 152. By extending the back side insulation layer 142 into a space between the second through via 152 and the semiconductor substrate 110, the increases in production cost and time associated with forming a separate via insulation layer can be avoided.

The back side insulation layer 142 may be formed of a plurality of layers. For example, the back side insulation layer 142 may include a first back side insulation layer 142A and a second back side insulation layer 142B formed on the first back side insulation layer 142A. Therefore, the first back side insulation layer 142A may be placed between the second back side insulation layer 142B and the semiconductor substrate 110. The first back side insulation layer 142A may extend between the second back side insulation layer 142B and the via insulation layer 141 by sequentially forming the first back side insulation layer 142A and the second back side insulation layer 142B on the via insulation layer 141,

As a material of the back side insulation layer 142, an insulating material such as silicon oxide and silicon nitride may be used. In an embodiment, the back side insulation layer 142 may include different insulating materials. For example, the first back side insulation layer 142A may include silicon oxide, and the second back side insulation layer 142B may include silicon nitride.

The back side insulation layer 142 may be formed by a deposition process such as chemical vapor deposition (CVD), physical vapor deposition (PVD), and atomic layer deposition (ALD).

A thickness t2 of the back side insulation layer 142 may be greater than or equal to the thickness t1 of the via insulation layer 141. For example, the thickness t2 of the back side insulation layer 142 may be about 0.3 μm to 1.5 μm or about 1.15 μm. The thickness t2 of the back side insulation layer 142 means a thickness in the vertical direction from the semiconductor substrate 110 or the second through via 152, which is covered by the back side insulation layer 142, toward the back side insulation layer 142. Since the second through via 152 has a lower aspect ratio (AR) than the first through via 151, the back side insulation layer 142 having a relatively thick thickness may be formed during the deposition process.

When the back side insulation layer 142 is formed of a plurality of back side insulation layers 142A and 142B, thicknesses t3 and t4 of the plurality of back side insulation layers 142A and 142B each may be greater than or equal to the thickness t1 of the via insulation layer 141. For example, the thickness t3 of the first back side insulation layer 142A may be about 0.8 μm, and the thickness t4 of the second back side insulation layer 142B may be about 0.35 μm.

The deposition process may form a region covering the side surface 152s of the second through via 152 of the back side insulation layers 142A, and 142B with a thinner thickness than a region covering the back side 110B and the bottom surface 152b of the semiconductor substrate 110.

The second pad 161 and the third pad 162 are arranged on the back side insulation layer 142 and may be connected to the first through via 151 and the second through via 152, respectively. The second pad 161 and the third pad 162 may be directly connected by contacting the first through via 151 and the second through via 152, respectively. The third pad 162 may be a dummy pad connected to the second through via 152 (i.e., the dummy via).

Each of the second pad 161 and the third pad 162 may be formed of a conductive material, and may include a metal such as, for example, copper (Cu), aluminum (Al), nickel (Ni), gold (Au), silver (Ag), palladium (Pd), titanium (Ti), or an alloy thereof. Depending on the need, the second pad 161 and/or third pad 162 may be formed of a plurality of conductivity layers (e.g., a plurality of metal layers). For example, the second pad 161 and the third pad 162 may include first metal layers 1611 and 1621 as seed layers and second metal layers 1612 and 1622 as plating layers on the first metal layers 1611 and 1621.

The second pad 161 and the third pad 162 may have a larger diameter than the first through via 151 and the second through via 152 and may extend over the back side insulation layer 142. In an embodiment, the second pad 161 and the third pad 162 may contact the back side insulation layer 142. The diameter of the second pad 161 and the diameter of the third pad 162 may be the same as or different from each other. For example, since the second through via 152 has a larger diameter than the first through via 151, the diameter of the third pad 162 may be formed to be larger than the diameter of the second pad 161.

According to the present disclosure, the heat dissipation characteristics of the semiconductor chip 100A can be improved by forming a heat dissipation path through the second through via 152 and the third pad 162 having high thermal conductivity. Increases in the production cost and time associated with forming a separate via insulation layer can be avoided by forming the via insulation layer of the second through via 152 together with the manufacturing of the back side insulation layer 142.

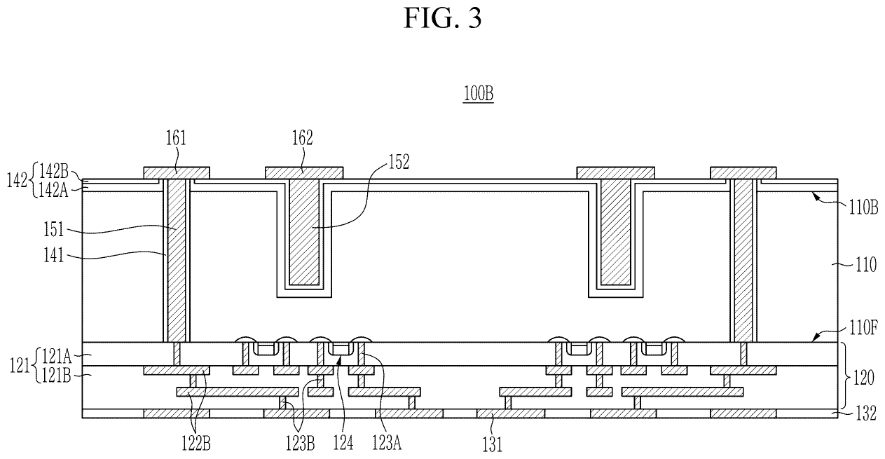

FIG. 3 is a cross-sectional view of a semiconductor chip according to another embodiment.

In a semiconductor chip 100B, a first through via 151 may be formed as a via first process performed before the FEOL process and BEOL process. For example, the first through via 151 may be formed before the FEOL process and the BEOL process. Therefore, the first through via 151 may penetrate a semiconductor substrate 110 and not penetrate a circuit structure 120. The lower end of the first through via 151 may be buried in the circuit structure 120. For example, the first through via 151 may be disposed at a level between a front side 110F and a back side 110B of the semiconductor substrate 110. The first through via 151 may be electrically connected to a first pad 131 via a wiring layer 122B.

For other configurations, the description specifically provided in the description of the semiconductor chip 100A according to an embodiment of the present disclosure may be equally applied.

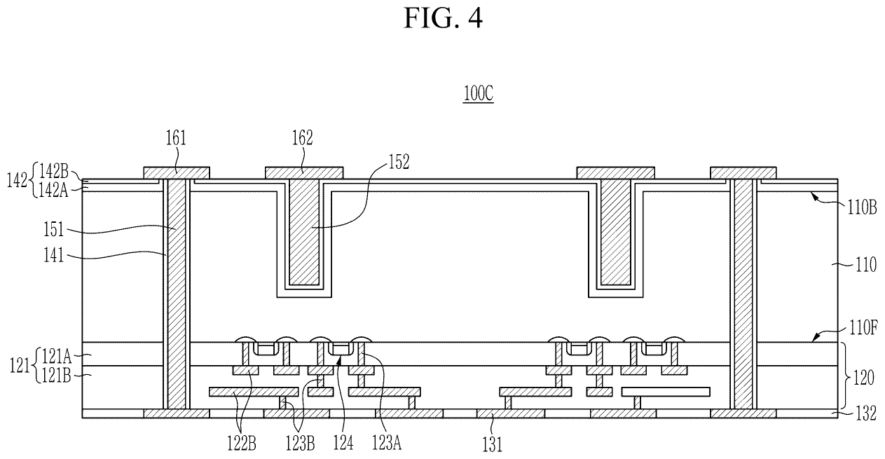

FIG. 4 is a cross-sectional view of a semiconductor chip according to another embodiment.

In a semiconductor chip 100C, a first through via 151 may be formed as a via last process performed after the FEOL process and BEOL process. For example, the first through via 151 may be formed after the FEOL process and the BEOL process. Unlike the second through via 152, the first through via 151 may be formed by processing a front side 110F of the semiconductor substrate 110 and may penetrate the entire semiconductor substrate 110. For example, the first through via 151 may penetrate the semiconductor substrate 110 and further penetrate the entire circuit structure 120. The first through via 151 may be directly connected to the first pad 131 by contacting the first pad 131.

For other configurations, the description specifically provided in the description of the semiconductor chip 100A according to an embodiment of the present disclosure may be equally applied.

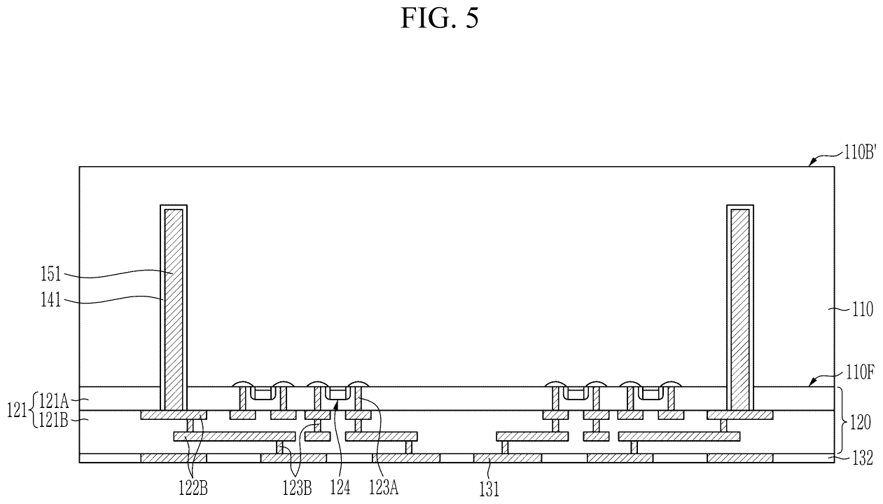

FIG. 5 to FIG. 11 show a manufacturing process of a semiconductor chip according to an embodiment.

First, referring to FIG. 5, the first through via 151 that penetrates a portion of the semiconductor substrate 110 in the vertical direction from the front side 110F of the semiconductor substrate 110 toward a preliminary back side 110B′ before processing of the semiconductor substrate 110 and is covered by the via insulation layer 141 is formed.

In an embodiment, the first through via 151 may be formed though a via middle process. A portion (e.g., FEOL process region) of the circuit structure 120 may be formed on the front side 110F of the semiconductor substrate 110 prior to forming the first through via 151. Thereafter, the first through via 151 may be formed by forming a via hole penetrating a part of the circuit structure 120 and a part of the semiconductor substrate 110, forming the via insulation layer 141 on a wall surface and a bottom surface of the via hole, and then filling the via hole 152h with a conductive material.

However, first through via 151 may also be formed as a via first or via last process. When the via first process is applied, the circuit structure 120 may be formed after the first through via 151 is formed. When the via-last process is applied, the circuit structure 120 may be formed before the first through via 151 is formed.

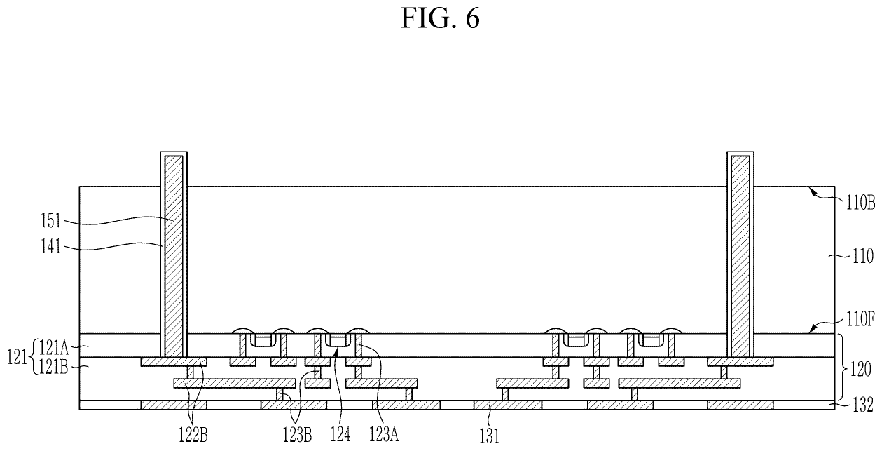

Next, referring to FIG. 6, a preliminary back side 110B′ of the semiconductor substrate 110 is removed by processing to form the back side 110B after processing, and the first through via 151 and the via insulation layer 141 are protruded onto the back side 110B of the semiconductor substrate 110. The back side 110B of the semiconductor substrate 110 may be removed by, for example, chemical mechanical polishing (CMP) or etching.

Next, referring to FIG. 7, a via hole 152h penetrating a portion of the semiconductor substrate 110 in the vertical direction from the back side 110B of the semiconductor substrate 110 toward the front side 110F of the semiconductor substrate 110 is formed. The via hole 152h may be formed by etching (dry etching or wet etching), for example, selective etching. A formation region of the via hole 152h of the semiconductor substrate 110 may be selectively removed by the selective etching.

The via hole 152h may be formed to have a diameter equal to or greater than the diameter d1 of the first through via 151. For example, a diameter d3 of the via hole 152h may be greater than the diameter d1 of the first through via 151.

The via hole 152h may be formed to have a depth of 50% or more of the thickness T1 of the semiconductor substrate 110 after the preliminary back side 110B′ is removed. For example, a depth T3 of the via hole 152h may be 50% or more of the thickness T1 of the semiconductor substrate 110.

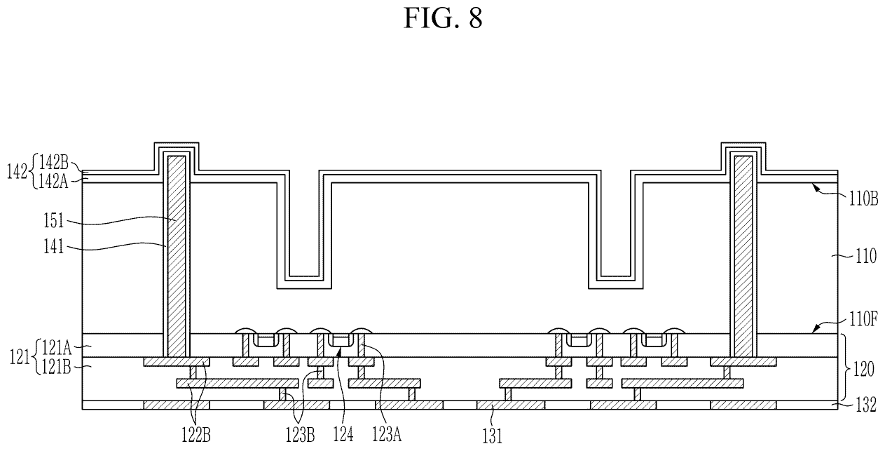

Next, referring to FIG. 8, a back side insulation layer 142 that covers the back side 110B of the semiconductor substrate 110, a region protruded onto the semiconductor substrate 110 of the via insulation layer 141 (a region covering the region protruded onto the semiconductor substrate 110 of the first through via 151), and the wall side 152s′ and the bottom side 152b′ of the via hole 152h is formed. The back side insulation layer 142 may be formed, for example, by depositing silicon oxide to form the first back side insulation layer 142A, and then depositing silicon nitride on the first back side insulation layer 142A to form the second back side insulation layer 142B.

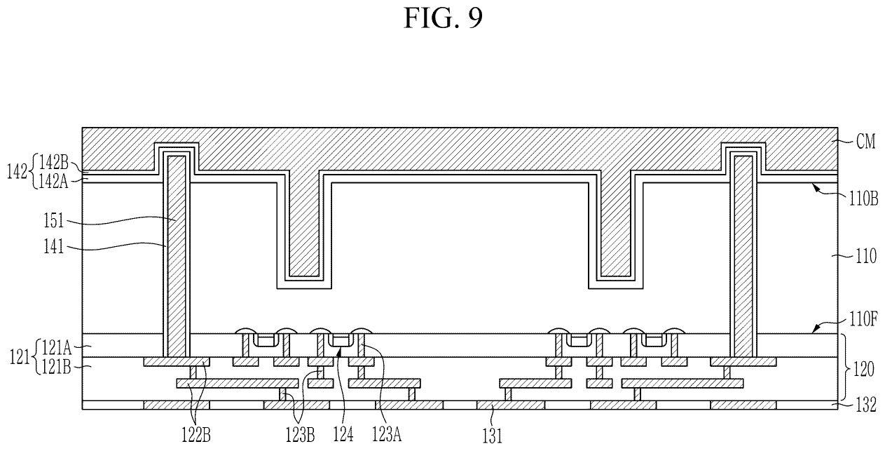

Next, referring to FIG. 9, the via hole 152h is filled with a conductive material CM. The conductive material CM may extend onto the back side 110B of the semiconductor substrate 110 to cover the back side insulation layer 142.

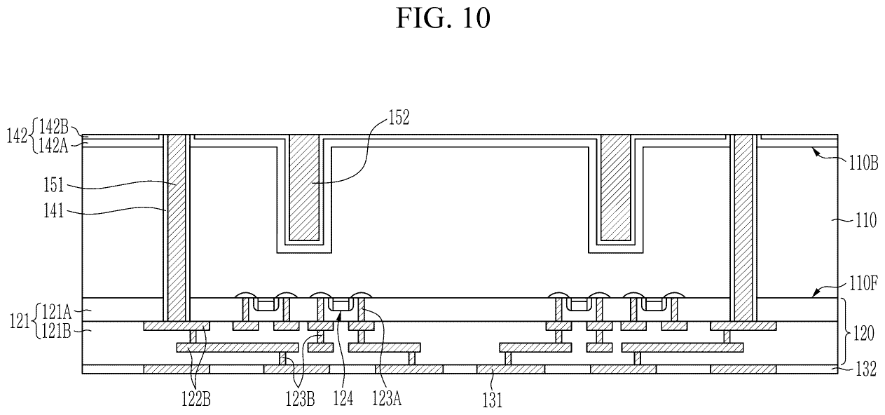

Next, referring to FIG. 10, a portion of the conductive material CM is removed to form the second through via 152, and a portion of each of the back side insulation layer 142 and the via insulation layer 141 is removed to expose the first through via 151.

When removing the conductive material CM, a region among the conductive material CM, located at a higher level than the region covering the back side 110B of the semiconductor substrate 110 of the back side insulation layer 142 may be removed, and the remaining conductive material CM may form the second through via 152. The conductive material CM may be removed by, for example, chemical mechanical polishing.

The back side insulation layer 142 and the via insulation layer 141 may be removed together with the conductive material CM. For example, the back side insulation layer 142 and the via insulation layer 141 may be removed by chemical mechanical polishing together with the conductive material CM. When removing the back side insulation layer 142 and the via insulation layer 141, a portion of the first through via 151 may be removed together. The second through via 152, the back side insulation layer 142, the via insulation layer 141, and the first through via 151 may be planarized by the chemical mechanical polishing, to thereby form a coplanar surface.

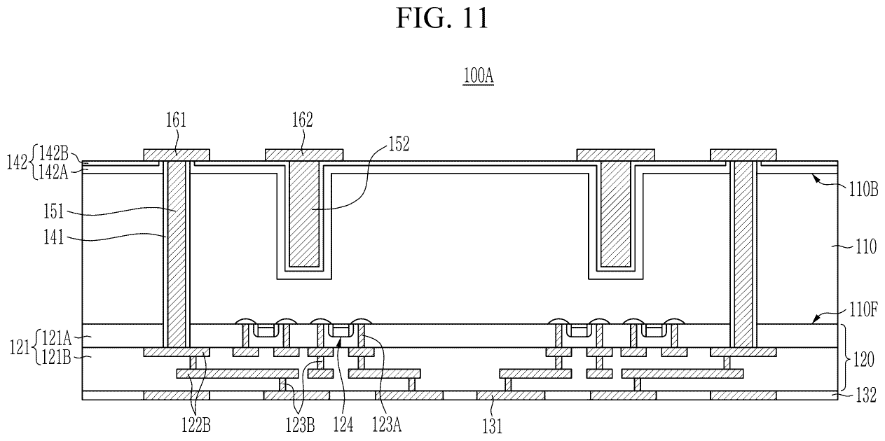

Finally, referring to FIG. 11, the semiconductor chip 100A according to an embodiment may be manufactured by forming the second pad 161 connected to the first through via 151 and the third pad 162 connected to the second through via 152. The second pad 161 and the third pad 162 may be manufactured by forming a seed layer on the first through via 151 and the second through via 152, and forming a plating layer on the seed layer.

Although the embodiments of the present disclosure have been described in detail above, the scope of the present disclosure is not limited thereto, and various modifications and improvements of a person of an ordinary skill in the art utilizing the basic concept of the present disclosure defined in the following claims also fall within the scope of the present disclosure.

The embodiments of the present disclosure are not independent of each other and may be implemented in combination with each other unless specifically contradictory. Accordingly, the combined embodiment of the present disclosure should also be considered as included in the present disclosure.

What is claimed is:

1. A semiconductor chip comprising:
a semiconductor substrate that includes a front side and a back side that are opposite to each other;
a circuit structure disposed on the front side of the semiconductor substrate;
a first through via that penetrates the semiconductor substrate in a vertical direction perpendicular to the front side of the semiconductor substrate and is electrically connected to the circuit structure; and
a dummy via buried in the semiconductor substrate, wherein a lower end of the dummy via is spaced apart from the back side of the semiconductor substrate.

2. The semiconductor chip of claim 1,
wherein a diameter of the dummy via is greater than or equal to a diameter of the first through via.

3. The semiconductor chip of claim 1,
wherein a diameter of the dummy via is 3.5 μm to 10 μm.

4. The semiconductor chip of claim 1,
wherein a height, in the vertical direction, of the dummy via is greater than 50% of a thickness, in the vertical direction, of the semiconductor substrate.

5. The semiconductor chip of claim 1,
wherein the first through via further extends into a part of the circuit structure in the vertical direction.

6. The semiconductor chip of claim 1,
wherein the first through via further penetrates the circuit structure in the vertical direction.

7. The semiconductor chip of claim 1,
wherein the first through via is disposed at a level between the front side of the semiconductor substrate and the back side of the semiconductor substrate.

8. The semiconductor chip of claim 1,
wherein the circuit structure comprises an individual device, and
wherein the dummy via is spaced apart from the individual device in the vertical direction.

9. The semiconductor chip of claim 8,
wherein at least a portion of the dummy via overlaps the individual device in the vertical direction.

10. The semiconductor chip of claim 1,
wherein thermal conductivity of the dummy via is greater than thermal conductivity of the semiconductor substrate.

11. A semiconductor chip comprising:
a semiconductor substrate that includes a front side and a back side that are opposite to each other;
a circuit structure disposed on the front side of the semiconductor substrate;
a first pad that is disposed on the circuit structure and electrically connected to the circuit structure;
a back side insulation layer that is disposed on the back side of the semiconductor substrate;
a first through via that penetrates the semiconductor substrate and the back side insulation layer in a vertical direction perpendicular to the front side of the semiconductor substrate, and is electrically connected to the circuit structure;
a via insulation layer that surrounds a side surface of the first through via;
a dummy via buried in the semiconductor substrate, wherein the dummy via extends from the back side insulation layer toward the front side of the semiconductor substrate in the vertical direction;
a second pad that is disposed on the back side insulation layer and connected to the first through via; and
a dummy pad that is disposed on the back side insulation layer and connected to the dummy via,
wherein the back side insulation layer extends into a space between the dummy via and the semiconductor substrate.

12. The semiconductor chip of claim 11,
wherein a thickness of the back side insulation layer is greater than or equal to a thickness of the via insulation layer.

13. The semiconductor chip of claim 11,
wherein the back side insulation layer comprises a first back side insulation layer and a second back side insulation layer, and
wherein the first back side insulation layer is disposed between the second back side insulation layer and the semiconductor substrate.

14. The semiconductor chip of claim 13,
wherein the first back side insulation layer extends into a space between the second back side insulation layer and the via insulation layer.

15. The semiconductor chip of claim 13,
wherein the first back side insulation layer contains silicon oxide, and
wherein the second back side insulation layer contains silicon nitride.

16. A semiconductor chip manufacturing method comprising:
forming a first through via covered with a via insulation layer in a semiconductor substrate having a front side and a preliminary back side which are opposite surfaces, wherein the first through via extends from the front side toward the preliminary back side in a vertical direction perpendicular to the front side of the semiconductor substrate;
partially removing the semiconductor substrate from the preliminary back side thereof to form a back side, thereby the first through via and the via insulation layer protruding beyond the back side of the semiconductor substrate;
forming a dummy via hole extending from the back side of the semiconductor substrate toward the front side thereof;
forming a back side insulation layer covering the back side of the semiconductor substrate, a region of the via insulation layer protruding beyond the back side of the semiconductor substrate, and a wall side and a bottom side of the dummy via hole;
forming a dummy via filling the dummy via hole;
removing a portion of each of the back side insulation layer and the via insulation layer to expose the first through via; and
forming a first pad connected to the first through via and a dummy pad connected to the dummy via.

17. The semiconductor chip manufacturing method of claim 16,
wherein a diameter of the dummy via hole is equal to or greater than a diameter of the first through via.

18. The semiconductor chip manufacturing method of claim 16,
wherein a height, in the vertical direction, of the dummy via is greater than 50% of a thickness, in the vertical direction, of the semiconductor substrate.

19. The semiconductor chip manufacturing method of claim 16,
wherein, in the forming the dummy via hole, the dummy via hole is formed by etching.

20. The semiconductor chip manufacturing method of claim 16,
wherein, in the exposing the first through via, the back side insulation layer and the via insulation layer are removed by chemical mechanical polishing.
